(19) United States
(12) Patent Application Publication
(10) Pub. No.: US 2017/0108919 A1
(43) Pub. Date: Apr. 20, 2017

(54) PORTABLE ELECTRONIC DEVICE

(71) Applicants: Yuki Tokuyama, Aichi (JP); Yosuke Tomita, Aichi (JP); Masayuki Motoki, Aichi (JP); Mitsuaki Kono, Tochigi (JP)

(72) Inventors: Yuki Tokuyama, Aichi (JP); Yosuke Tomita, Aichi (JP); Masayuki Motoki, Aichi (JP); Mitsuaki Kono, Tochigi (JP)

(73) Assignee: OMRON AUTOMOTIVE ELECTRONICS CO., LTD., Aichi (JP)

(21) Appl. No.: 15/293,350

(22) Filed: Oct. 14, 2016

(30) Foreign Application Priority Data
Oct. 14, 2015 (JP) 2015-202542

(51) Int. Cl. G06F 3/01; B60R 25/24

(52) U.S. Cl. CPC G06F 3/011; B60R 25/24; H03K 17/955

(57) ABSTRACT

A portable electronic device includes: a housing that is configured to be held by one hand of a human being; a holding detection unit that detects holding of the housing by the one hand; an input operation detection unit that detects an input operation; and a control section that outputs a control signal based on detection results of the holding detection unit and the input operation detection unit. The control section validates the input operation detection unit if the holding of the housing is detected by the holding detection unit, and after the validation, outputs a control signal based on a detection result of the input operation detection unit regardless of the detection result of the holding detection unit.

### CROSS-REFERENCES TO RELATED APPLICATIONS

This application is based upon and claims the benefit of priority from Japanese Patent Application No. 2015-202542, filed on Oct. 14, 2015; the entire contents of which are incorporated herein by reference.

### FIELD

One or more embodiments of the present invention relate to a portable electronic device to which an input operation can be performed while being held by one hand.

### BACKGROUND

As a portable electronic device to which an input operation can be performed while being held by one hand, there are devices disclosed in JP-A-2014-137738, JP-A-2012-220967, JP-A-2015-21304, and JP-A-2012-63976.

The portable electronic devices disclosed in JP-A-2014-137738 and JP-A-2012-220967 include a smart phone and the like, and include a housing formed in a thin rectangular parallelepiped shape. A display section such as a display or a touch panel is provided on a front surface (upper surface) which has the widest projected area of the housing. A control section that outputs a control signal is provided inside the housing.

In JP-A-2014-137738, an input operation detection unit which includes a proximity sensor, which can be operated by a thumb of one hand in a state where the housing is held by the one hand is provided on a side surface portion sandwiched between the upper surface and the lower surface of the housing. The control section outputs a control signal according to the presence or absence of the input operation performed by a hand of a human being, an operation location, and an operation direction that are detected by the input operation detection unit, and a display content and the like of the display section are updated on the basis of the control signal.

In JP-A-2012-220967, an input operation detection unit (input device) such as an acceleration sensor, a capacitive sensor, a touch panel, or a mechanical switch is provided on the surface of or inside the housing. In addition, a plurality of holding detection units (holding sensors) including an electric field sensor or a capacitive sensor are provided on a side surface (surface perpendicular to the touch panel) of the housing with which a finger of one hand is in contact in a state where the housing is held by the one hand such that the touch panel is visually observed. In order to prevent the malfunction caused by detecting an input operation which is not intended by the user, when holding of the housing by one hand is detected by the holding detection unit, the control section performs a predetermined signal process by regarding the input operation detected by the input operation detection unit as being valid.

In the portable electronic devices disclosed in JP-A-2014-137738 and JP-A-2012-220967, it is assumed that an input operation section is operated while the display section such as a display or a touch panel is watched. Meanwhile, in the portable electronic devices disclosed in JP-A-2015-21304 and JP-A-2012-63976, a simple structure with no display section such as a display or a touch panel is adopted in which an input operation can be performed without visual observation in a state where the housing is held by one hand, in order to improve convenience.

The portable electronic device disclosed in JP-A-2015-21304 includes electronic keys for a vehicle, and includes a housing that can be held by one hand. A curved surface portion having a concave-convex shape is formed on an operation surface (surface perpendicular to the side surface) which has the widest projected area of the housing. A plurality of switches operated by the thumb are arranged on the curved surface portion in a direction in which the concave-convex shape changes. The housing is held by one hand in a manner in which the rear side of the convex-shaped curved surface portion is supported by an index finger and the rear side of the concave-shaped curved surface portion is supported by a little finger. In doing so, when the thumb of the one hand is slid in the direction in which the concave-convex shape of the curved surface portion changes, the user can smoothly operate each switch without greatly separating the thumb from the operation surface.

The portable electronic device disclosed in JP-A-2012-63976 includes a housing that can be held by one hand. Slide touch sensors and operation buttons having a concave shape or a convex shape are provided on an operation surface of the housing. The slide touch sensors are arranged to be orthogonal to each other in a longitudinal direction and a lateral direction. The operation buttons are arranged to be deviated from the center of the operation surface. In a state where the housing is held by one hand, the orientation of the operation surface can be recognized by the tactile impression of the operation buttons without visual observation of the portable electronic device. The slide touch sensor or the operation buttons can be correctly operated by changing the way of holding the housing such that the operation surface is oriented in a correct direction in terms of operation.

As in JP-A-2012-220967, when holding of the housing by one hand is detected by the holding detection unit, if a control process is performed by regarding the input operation detected by the input operation detection unit as being valid, it is possible to prevent the malfunction of the portable electronic device caused by an input operation which is not intended by the user.

In order to improve the accuracy of detecting the holding of the housing by one hand, it is preferable that plural holding detection units are provided on the housing. In doing so, however, the manufacturing costs and the power consumption may be increased. Specifically, in a case where an electric field sensor or a capacitive sensor is used as the holding detection unit, since the sensor needs to be always energized, the power consumption is further increased.

Meanwhile, if the number of installed holding detection units is small, it is possible to reduce the manufacturing costs and the power consumption. However, the possibility of the holding state not being detected when one hand holding the housing is separated from the holding detection unit and the input operation being regarded as invalid is increased. That is, the operability is decreased.

### SUMMARY

An object of one or more embodiments of the invention is to provide a portable electronic device which can implement prevention of malfunction, reduction of manufacturing costs and current consumption, and improvement of operability.

According to one or more embodiments of the invention, there is provided a portable electronic device including a housing that is configured to be held by one hand of a human being; a holding detection unit that detects holding of the housing by the one hand; an input operation detection unit that detects an input operation; and a control section that outputs a control signal based on detection results of the holding detection unit and the input operation detection unit. The control section validates the input operation detection unit if the holding of the housing is detected by the holding detection unit, and after the validation, outputs a control signal based on a detection result of the input operation detection unit regardless of the detection result of the holding detection unit.

According to the above description, the input operation detection unit is validated after the holding of the housing is detected by the holding detection unit, and the control signal is output on the basis of the detection result of the input operation detection unit. Therefore, it is possible to prevent the malfunction of the portable electronic device due to an input operation which is not intended by a user. In addition, in a case where the holding of the housing is detected once by the holding detection unit, then, the control signal is output on the basis of the detection result of the input operation detection unit regardless of the detection result of the holding detection unit. Therefore, after the housing is held by one hand such that the fingers of the one hand approach the holding detection unit, even if the fingers become separated from the holding detection unit when the input operation is performed, the input operation is detected by the input operation detection unit, and a control signal is output. That is, it is not necessary to dispose multiple holding detection units on the housing for continuously detecting the holding of the housing by one hand even when the input operation is performed, and thus a minimum number of holding detection units necessary for temporarily detecting the holding of the housing by one hand may be disposed on the housing. Therefore, it is possible to reduce manufacturing costs and the current consumption. When the input operation is performed, it is not necessary to maintain the approaching state of one hand with respect to the holding detection unit. Therefore, priority is given to the input operation that is performed on the input operation detection unit, and it is possible to improve the operability. Thus, in the portable electronic device, it is possible to realize prevention of malfunction, reduction of manufacturing costs and current consumption, and improvement of operability.

In the portable electronic device according to one or more embodiments of the invention, the control section may invalidate the holding detection unit and validate the input operation detection unit within a predetermined time after holding of the housing is detected by the holding detection unit, and output a control signal based on the detection result of the input operation detection unit, and the control section may validate the holding detection unit and invalidate the input operation detection unit before the holding detection unit detects the holding of the housing or after the predetermined time elapses after the holding of the housing is detected.

In the portable electronic device according to one or more embodiments of the invention, the housing may include a stable surface that is a surface having a widest projected area, and a side surface portion that is present on a side of the stable surface, and the holding detection unit and the input operation detection unit may be disposed on the side surface portion.

In the portable electronic device according to one or more embodiments of the invention, a plurality of the holding detection units may be symmetrically disposed on the side surface portion of the housing.

In the portable electronic device according to one or more embodiments of the invention, the holding detection unit may include a plurality of sensors that detect approaching or movement of a human body, and when the plurality of sensors detect the approaching or the movement of the human body within a predetermined time, the control section may determine that the housing is being held.

The portable electronic device according to one or more embodiments of the invention may include a keyless remote controller for a vehicle, and may further include a communication section that transmits a radio signal to a vehicle-mounted control device that is mounted in a vehicle, based on the control signal output from the control section.

In the portable electronic device according to one or more embodiments of the invention, the holding detection unit may also serve as the input operation detection unit.

According to one or more embodiments of the invention, it is possible to provide a portable electronic device which can implement prevention of malfunction, reduction of manufacturing costs and current consumption, and improvement of operability.

### BRIEF DESCRIPTION OF THE DRAWINGS

FIG. 1 is a diagram illustrating an electrical configuration of a portable electronic device according to an embodiment of the invention;

FIG. 2 is a perspective view illustrating the portable electronic device of FIG. 1;

FIGS. 3A and 3B are diagrams illustrating examples of a holding state of the portable electronic device of FIG. 1;

FIG. 4 is a diagram illustrating another example of the holding state of the portable electronic device of FIG. 1;

FIG. 5 is a flowchart illustrating an operation of the portable electronic device of FIG. 1;

FIG. 6 is a perspective view illustrating a portable electronic device according to another embodiment;

FIGS. 7A to 7D are diagrams illustrating examples of a holding state of the portable electronic device of FIG. 6;

FIG. 8 is a perspective view illustrating a portable electronic device according to another embodiment;

FIG. 9 is a flowchart illustrating an operation of a portable electronic device according to another embodiment; and

FIG. 10 is a perspective view illustrating a portable electronic device according to another embodiment.

### DETAILED DESCRIPTION

In embodiments of the invention, numerous specific details are set forth in order to provide a thorough understanding of the invention. However, it will be apparent to one of ordinary skill in the art that the invention may be practiced without these specific details. In other instances, well-known features have not been described in detail to avoid obscuring the invention.

Hereinafter, embodiments of the invention will be described with reference to the drawings. In the respective drawings, the same portions or the corresponding portions are given the same reference numerals.

First, the configuration of a portable electronic device is described.

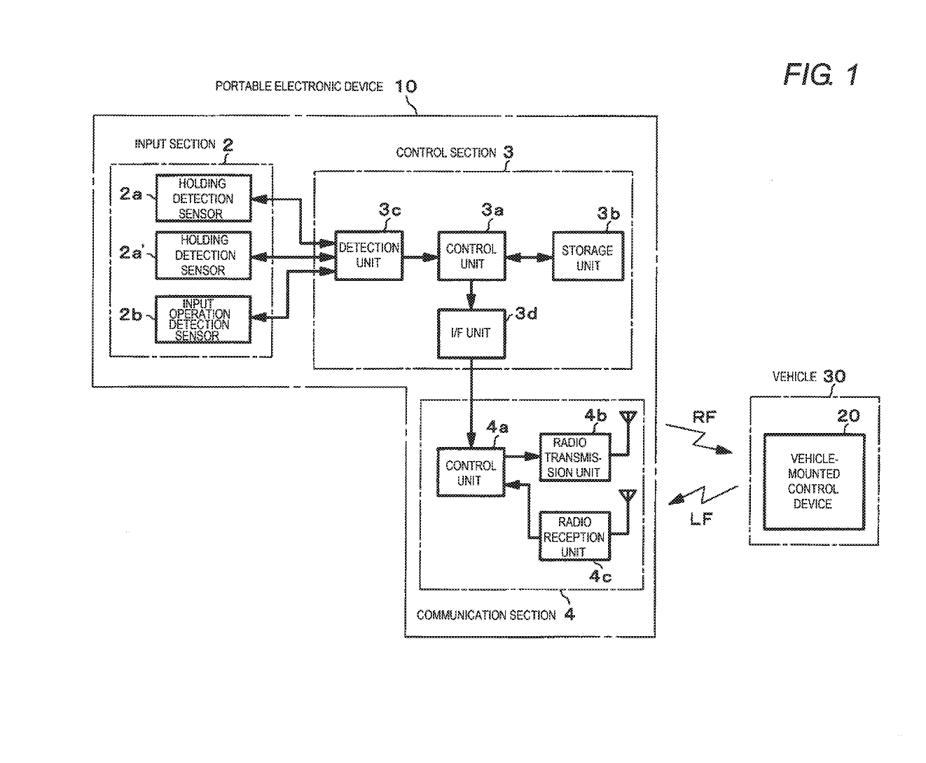

FIG. 1 is a diagram illustrating an electrical configuration of a portable electronic device 10. The portable electronic device 10 includes a keyless remote controller (FOB) for a vehicle, and is carried by a user. The portable electronic device 10 includes an input section 2, a control section 3, and a communication section 4.

The input section 2 is configured to include holding detection sensors 2a and 2a′ and an input operation detection sensor 2b. These sensors 2a, 2a′, and 2b include capacitance type proximity sensors, and detect approaching or movement of a human body. The holding detection sensors 2a and 2a′ are an example of “the holding detection unit” according to one or more embodiments of the invention, and the input operation detection sensor 2b is an example of “the input operation detection unit” according to one or more embodiments of the invention.

The control section 3 is configured to include a control unit 3a, a storage unit 3b, a detection unit 3c, and an interface (I/F) unit 3d. The control unit 3a includes a CPU, and the storage unit 3b includes a memory.

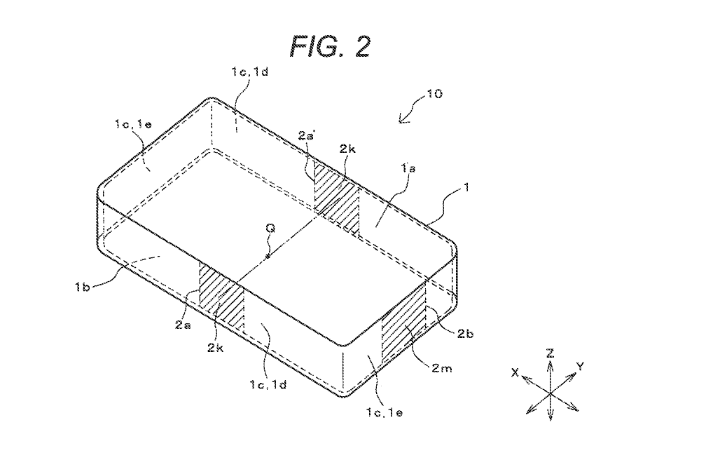

The detection unit 3c includes a circuit for detecting the electrostatic capacity between electrodes of the sensors 2a, 2a′, and 2b. The control unit 3a detects approaching or movement of an operating body such as a hand or a finger of a human being with respect to the sensors 2a, 2a′, and 2b on the basis of the change of the electrostatic capacity detected by the detection unit 3c. Then, the control unit 3a determines that a housing 1 (refer to FIG. 2 described below) of the portable electronic device 10 is held by one hand on the basis of the detection results of the holding detection sensors 2a and 2a′. In addition, the control unit 3a determines an input operation with respect to the portable electronic device 10 on the basis of the detection result of the input operation detection sensor 2b.

The I/F unit 3d includes a circuit for the communication between the control section 3 and the communication section 4. The control unit 3a outputs a control signal to the communication section 4 on the basis of the input operation detected by the input operation detection sensor 2b. The storage unit 3b stores information and the like for the control unit 3a controlling each section.

The communication section 4 is configured to include a control unit 4a, a radio transmission unit 4b, and a radio reception unit 4c. The control unit 4a includes a CPU and a memory. The radio transmission unit 4b includes a circuit for transmitting a radio frequency (RF) signal in a wireless manner. The radio reception unit 4c includes a circuit for receiving a low frequency (LF) signal in a wireless manner.

The control unit 4a transmits an RF signal to a vehicle-mounted control device 20 mounted in a vehicle 30 by using the radio transmission unit 4b on the basis of the control signal output from the control unit 3a of the control section 3. Specifically, the control unit 4a transmits a keyless entry signal (RF signal) for requesting locking and unlocking of the door of the vehicle 30, to the vehicle-mounted control device 20 by using the radio transmission unit 4b. The keyless entry signal includes a unique ID mode assigned to the portable electronic device 10. The vehicle-mounted control device 20 performs collation of ID of the portable electronic device 10 when the keyless entry signal is received, and allows the locking and unlocking of the door of the vehicle 30 when the collation is successful.

In addition, the vehicle-mounted control device 20 transmits a response request signal (LF signal) to the portable electronic device 10 in a case of passive entry or starting the engine of the vehicle. If the response request signal is received by the radio reception unit 4c of the communication section 4, the control unit 4a sends back a response signal (RF signal) including the ID code of the portable electronic device 10 to the vehicle-mounted control device 20 by using the radio transmission unit 4b. The vehicle-mounted control device 20 performs collation of the ID of the portable electronic device 10 when the response signal is received, and allows the locking and unlocking of the door or the starting of the engine of the vehicle 30 when the collation is successful.

Next, the structure of the portable electronic device 10 will be described.

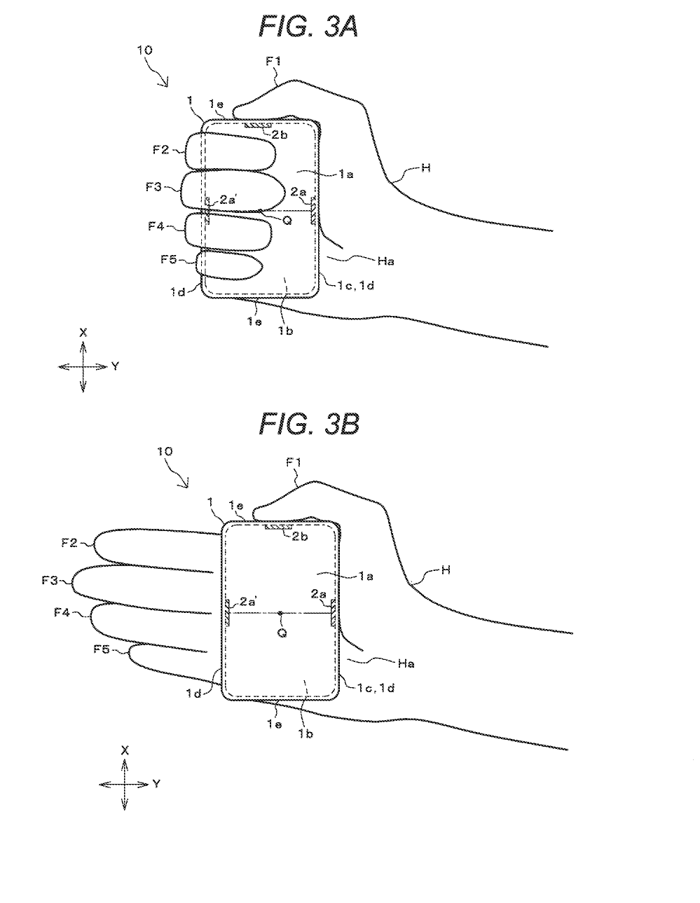

FIG. 2 is a perspective view illustrating the portable electronic device 10. FIGS. 3A and 3B are diagrams illustrating examples of a holding state of the portable electronic device 10.

As illustrated in FIG. 2, the portable electronic device 10 includes the housing 1 that is formed approximately in a thin rectangular parallelepiped shape. As illustrated in FIG. 3A, the housing 1 has a size so as to be held by one hand H of the human being. The housing 1 accommodates respective sections 2 to 4 of FIG. 1.

As illustrated in FIG. 2, the housing 1 has a symmetric shape in three axis directions X, Y, and Z which are orthogonal to each other, and the dimensions of the three axis directions X, Y, and Z are different from each other. Specifically, the dimension of the housing 1 in the X-axis direction is the longest, and the dimension of the housing 1 in the Z-axis direction is the shortest. The X-axis direction is a longitudinal direction of the housing 1, the Y-axis direction is a lateral direction of the housing 1, and the Z-axis direction is a thickness direction of the housing 1.

As illustrated in FIG. 2, the housing 1 includes stable surfaces 1a and 1b and a side surface portion 1c. The stable surfaces 1a and 1b are front surfaces having the widest projected area of the housing 1. In FIG. 2, the stable surface 1a is a flat upper surface of the housing 1, and the stable surface 1b is a flat lower surface of the housing 1. The side surface portion 1c is a rectangular frame-shaped portion which is present on the side of the stable surfaces 1a and 1b, and includes side surfaces 1d and 1e that continue to the stable surfaces 1a and 1b, and a region inside the side surfaces 1d and 1e and close to the side surfaces 1d and 1e. The side surface 1d is a flat surface orthogonal to the lateral direction Y of the housing 1, and the side surface 1e is a flat surface orthogonal to the longitudinal direction X of the housing 1. The projected area of the side surface 1d is set to be wider than the projected area of the side surface 1e.

The projected areas of the stable surfaces 1a and 1b of the housing 1 are set to be wider than the projected area of the side surface 1d. Therefore, as illustrated in FIG. 3A, it is possible to stably hold the portable electronic device 10 by gripping the housing 1 with the one hand H such that one of the stable surfaces 1a and 1b is in contact with a palm Ha of the one hand H. In the example of FIG. 3A, the housing 1 is held by the one hand H such that the lower surface 1b is in contact with the palm Ha of the one hand H.

As illustrated in FIG. 3A, it is possible to further stably hold the portable electronic device 10 by gripping the housing 1 with the one hand H such that a direction in which fingers F2 to F5 except for the thumb F1 of the hand H are lined side by side is parallel with the X-axis direction (longitudinal direction) of the housing 1.

Although not illustrated, it is possible to stably place the portable electronic device 10 by putting the housing 1 on a placing surface such that one of the stable surfaces 1a and 1b is in contact with the placing surface of another object.

As illustrated in FIG. 2, the sensors 2a, 2a′, and 2b are disposed on the side surface portion 1c of the housing 1. Specifically, the holding detection sensors 2a and 2a′ are disposed in the vicinity of each side surface 1d of the side surface portion 1c so as to make a pair in a line-symmetric shape with respect to a straight line that passes through the center Q of the housing 1 and is parallel with the X axis. Detection surfaces 2k of the holding detection sensors 2a and 2a′ are parallel with the side surfaces 1d, and face a side opposite to the center Q of the housing 1. The input operation detection sensor 2b is disposed in the vicinity of one side surface 1e of the side surface portion 1c. A detection surface 2m of the input operation detection sensor 2b is parallel with the one side surface 1e, and faces a side opposite to the center Q of the housing 1.

In FIG. 2, the sensors 2a, 2a′, and 2b are not exposed from the side surfaces 1d and 1e of the housing 1, but these sensors may be exposed from the side surfaces 1d and 1e. In addition, in a case where the sensors 2a, 2a′, and 2b are exposed from the side surfaces 1d and 1e, the front surfaces of the sensors 2a, 2a′, and 2b may be or may not be on the same plane as the side surfaces 1d and 1e.

As illustrated in FIG. 3A, when the housing 1 is held by the one hand H, the thumb F1 of the one hand H is in contact with one side surface 1e, and the other fingers F2 to F5 or the palm Ha is in contact with the side surface d. In this example, since the detection surfaces 2k of the holding detection sensors 2a and 2a′ are made to respectively face the side surfaces 1d, the holding detection sensors 2a and 2a′ detect approaching or movement of a hand of a human being with respect to the side surface 1d. In addition, since the detection surface 2m of the input operation detection sensor 2b is made to face the side surface 1e, the input operation detection sensor 2b detects approaching or movement of a hand of a human being with respect to the side surface 1e.

As another example, the detection ranges of the sensors 2a, 2a′, and 2b may be expanded to edge parts of the stable surfaces 1a and 1b.

In a holding state as illustrated in FIG. 3A, a part (part on the arm side) of the palm Ha of the one hand H approaches (or is in contact with) the holding detection sensor 2a, and at least one of the middle finger F3 and the ring finger F4 approaches (or is in contact with) the holding detection sensor 2a′. Then, the electrostatic capacity of the holding detection sensors 2a and 2a′ is changed, and therefore, the holding of the housing 1 by the one hand H is detected by the detection unit 3c and the control unit 3a of FIG. 1.

In the holding state as illustrated in FIG. 3A, the thumb F1 of the one hand H that has approached (or has been in contact with) one side surface 1e of the housing 1 performs a sliding operation in the Y-axis direction. Then, the electrostatic capacity of the input operation detection sensor 2b facing the thumb F is changed, and therefore, the input operation (sliding operation) by the thumb F1 of the one hand H is detected by the detection unit 3c and the control unit 3a.

As another example, the thumb F1 performs a touching operation or a knocking operation with respect to one side surface 1e of the housing 1, and thus the operation may be detected as an input operation by the input operation detection sensor 2b, the detection unit 3c, and the control unit 3a.

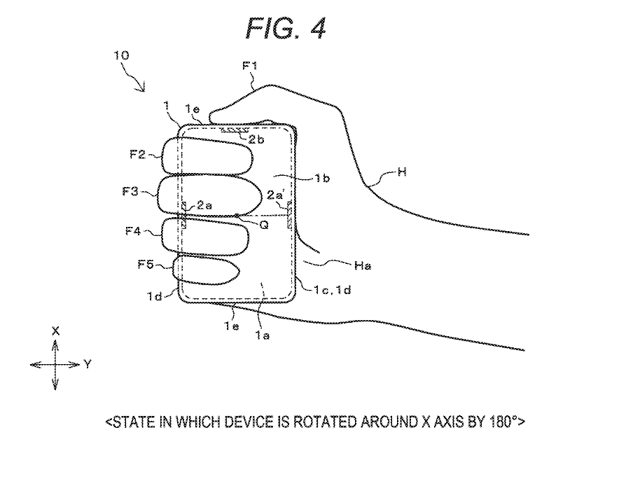

In a case where the housing 1 is rotated with respect to the center Q about the X axis by 180° from the state of FIG. 3A, and similarly, the housing 1 is held by the one hand H, as illustrated in FIG. 4, a part (part on the arm side) of the palm Ha of the one hand H approaches (or is in contact with) the holding detection sensor 2a′, and at least one of the middle finger F3 and the ring finger F4 approaches (or is in contact with) the holding detection sensor 2a. Also in this case, the electrostatic capacity of the holding detection sensors 2a and 2a′ is changed, and therefore, the holding of the housing 1 by the one hand H is detected by the detection unit 3c and the control unit 3a of FIG. 1. In this holding state, if the thumb F1 performs a sliding operation in the Y-axis direction with respect to the side surface 1e that faces the thumb F1, the electrostatic capacity of the input operation detection sensor 2b is changed, and therefore, the input operation by the thumb F1 of the one hand H is detected by the detection unit 3c and the control unit 3a.

Next, the operation of the portable electronic device 10 will be described.

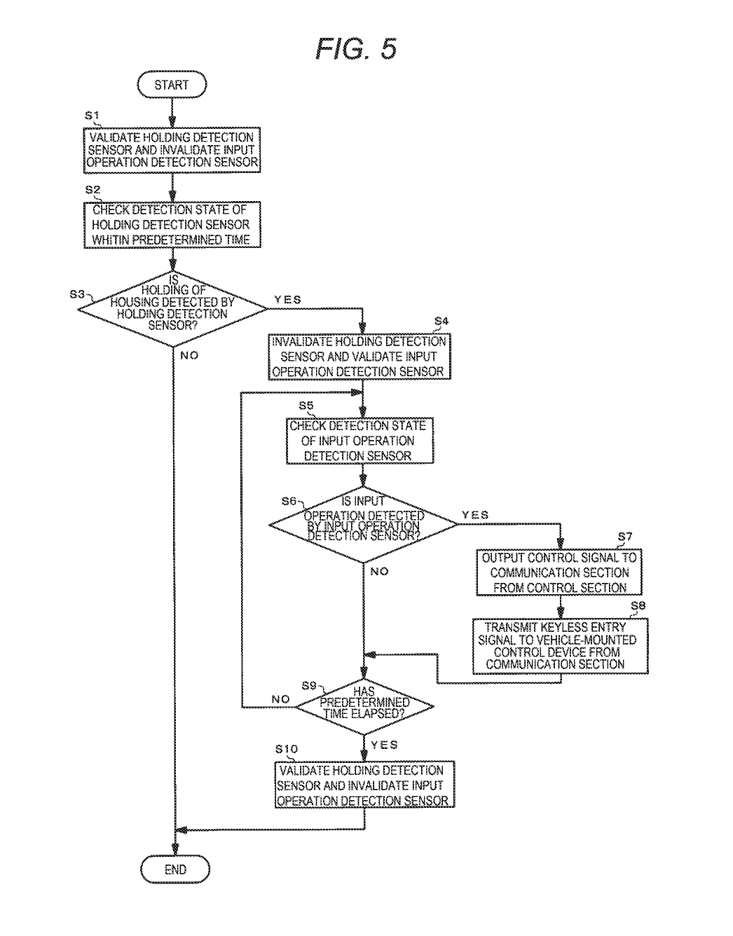

FIG. 5 is a flowchart illustrating the operation of the portable electronic device 10. Until the holding of the housing 1 is detected, the control unit 3a of the control section 3 validates the holding detection sensors 2a and 2a′, and invalidates the input operation detection sensor 2b (step S1).

The validation of the sensors 2a, 2a′, and 2b is that electricity is supplied to the sensors 2a, 2a′, and 2b and the detection states of the sensors 2a, 2a′, and 2b are monitored. In addition, the invalidation of the sensors 2a, 2a′, and 2b may be that electricity is supplied to the sensors 2a, 2a′, and 2b, but the detection states of the sensors are not monitored, or may be that the supply of electricity to the sensors 2a, 2a′, and 2b is stopped.

Next, the control unit 3a checks the detection states of the holding detection sensors 2a and 2a′ within a predetermined time by using the detection unit 3c (step S2). Here, if the amount of change in the electrostatic capacity of the holding detection sensors 2a and 2a′ is not equal to or greater than a threshold value within a predetermined time, the control unit 3a determines that the holding of the housing 1 by the one hand H is not detected by the holding detection sensors 2a and 2a′ (step S3: NO). In this case, the states of the validation of the holding detection sensors 2a and 2a′ and the invalidation of the input operation detection sensor 2b continue. The process from step S1 is repeated again.

As illustrated in FIG. 3A or FIG. 4, if the housing 1 is held by the one hand H, the electrostatic capacity of the holding detection sensors 2a and 2a′ is changed. In a case where the detection unit 3c detects that the amount of change in the electrostatic capacity of the holding detection sensors 2a and 2a′ is equal to or greater than a threshold value within a predetermined time, the control unit 3a determines that the holding of the housing 1 by the one hand H is detected by the holding detection sensors 2a and 2a′ (step S3: YES). Then, the control unit 3a invalidates the holding detection sensors 2a and 2a′ and validates the input operation detection sensor 2b (step S4).

Next, the control unit 3a checks the detection state of the input operation detection sensor 2b by using the detection unit 3c (step S5). In this state, if a sliding operation is not performed by the hand on the side surface 1e that faces the input operation detection sensor 2b, the electrostatic capacity of the input operation detection sensor 2b is not changed to a predetermined state, and thus the control unit 3a determines that the input operation is not detected by the input operation detection sensor 2b (step S6: NO).

In this manner, if a predetermined time elapses after the detection of the holding of the housing 1 (step S3: YES) without the detection of the input operation (step S9: YES), the control unit 3a validates the holding detection sensors 2a and 2a′ and invalidates the input operation detection sensor 2b (step S10). Then, process from step S1 is repeated again.

Meanwhile, if a sliding operation is performed on the side surface 1e that faces the input operation detection sensor 2b by the thumb F1 of the one hand H within a predetermined time after holding of the housing 1 by the one hand H is detected (step S3: YES), the electrostatic capacity of the input operation detection sensor 2b is changed to a predetermined state. Therefore, the control unit 3a determines that the input operation is detected by the input operation detection sensor 2b (step S6: YES).

Then, the control unit 3a outputs a control signal to the communication section 4 on the basis of the input operation regardless of the change of the detection results of the holding detection sensors 2a and 2a′ (step S7). In a case where a control signal is input from the control section 3, the control unit 4a of the communication section 4 transmits a keyless entry signal to the vehicle-mounted control device 20 by using the radio transmission unit 4b (step S8).

If a predetermined time elapses after the detection of the holding of the housing 1 (step S3: YES) (step S9: YES), the control unit 3a validates the holding detection sensors 2a and 2a′ and invalidates the input operation detection sensor 2b (step S10). Then, process from step S1 is repeated again.

According to the embodiment described above, the input operation detection sensor 2b is validated after the holding of the housing 1 by the one hand H is detected by the holding detection sensors 2a and 2a′. Then, a control signal is output from the control section 3 to the communication section 4 on the basis of the detection result of the input operation detection sensor 2b, and a keyless entry signal is transmitted to the vehicle-mounted control device 20 by using the radio transmission unit 4b. Therefore, it is possible to prevent the malfunction of the portable electronic device 10 caused by an input operation which is not intended by the user.

In addition, in a case where the holding of the housing 1 by the one hand H is detected once by the holding detection sensors 2a and 2a′, then, a control signal is output on the basis of the detection result of the input operation detection sensor 2b regardless of the detection results of the holding detection sensors 2a and 2a′ (that is, even in a case where the holding is no more detected). Therefore, after the housing 1 is held by the one hand H such that the palm Ha and the fingers F3 and F4 approach the holding detection sensors 2a and 2a′ as illustrated in FIG. 3A, even if the fingers F3 and F4 become separated from the holding detection sensor 2a′ as illustrated in FIG. 3B when the input operation is performed, the input operation by thumb F1 is detected by the input operation detection sensor 2b. Then, a control signal is output from the control section 3 on the basis of the input operation, and a keyless entry signal is transmitted to the vehicle-mounted control device 20. That is, it is not necessary to dispose multiple holding detection sensors on the housing 1 for continuously detecting the holding of the housing 1 by the one hand H even when the input operation is performed, and thus a minimum number of holding detection sensors 2a and 2a′ necessary for temporarily detecting the holding of the housing 1 by the one hand H may be disposed on the housing 1. Therefore, it is possible to reduce manufacturing costs and the current consumption. When the input operation is performed, it is not necessary to maintain the approaching state of the one hand H with respect to the holding detection sensors 2a and 2a′. Therefore, priority is given to the input operation that is performed on the input operation detection sensor 2b, and it is possible to improve the operability.

Thus, in the portable electronic device 10, it is possible to realize prevention of malfunction, reduction of manufacturing costs and current consumption, and improvement of operability.

In the embodiment described above, within a predetermined time after holding of the housing 1 by the one hand H is detected by the holding detection sensors 2a and 2a′, the holding detection sensors 2a and 2a′ are invalidated, the input operation detection sensor 2b is validated, and the control section 3 outputs a control signal to the communication section 4 on the basis of the detection result of the input operation detection sensor 2b. Therefore, even if the fingers F3 and F4 and the palm Ha become separated from the holding detection sensors 2a and 2a′ within a predetermined time after holding of the housing 1 by the one hand H is detected, the input operation is detected by the input operation detection sensor 2b, and thus it is possible to normally operate the portable electronic device 10 and to improve the operability.

In the embodiment described above, before the holding of the housing 1 by the one hand H is detected by the holding detection sensors 2a and 2a′, or after a predetermined time elapses after the holding of the housing 1 is detected, the holding detection sensors 2a and 2a′ are validated, and the input operation detection sensor 2b is invalidated. Therefore, it is possible to prevent the malfunction of the portable electronic device 10 caused by an input operation which is not intended except for a case in which the user holds the housing 1 for performing the input operation.

In the embodiment described above, the stable surfaces 1a and 1b having wide projected areas are provided on the housing 1, and the holding detection sensors 2a and 2a′ and the input operation detection sensor 2b are disposed on the side surface portion 1c of the housing 1 which is present on the side of the stable surfaces 1a and 1b. Therefore, one of the stable surfaces 1a and 1b is easily in contact with another object, and thus it is possible to stably place the portable electronic device 10. In addition, in a case where the housing 1 is held by the one hand H, one of the stable surfaces 1a and 1b is easily in contact with the palm Ha of the one hand H, and thus it is possible to stably hold the portable electronic device 10 (FIG. 3A and FIG. 4). In addition, in a case where the housing 1 is held by the one hand H, since the palm Ha and the fingers F1 to F5 are in contact with the side surfaces 1d and 1e, it becomes easy that the holding of the housing 1 by the one hand H is detected by the holding detection sensors 2a and 2a′ disposed on the side surface portion 1c, and the input operation by the thumb F1 is detected by the input operation detection sensor 2b. Furthermore, since the side surfaces 1d and 1e have smaller projected areas than those of the stable surfaces 1a and 1b of the housing 1, and it is difficult for an object or a human being to unintentionally come into contact with the side surfaces, it is possible to prevent the erroneous detection by the holding detection sensors 2a and 2a′ and the input operation detection sensor 2b, which are disposed in the vicinity of the side surfaces 1d and 1e, and to prevent the malfunction of the portable electronic device 10.

In the embodiment described above, the holding detection sensors 2a and 2a′ are symmetrically disposed on the respective side surfaces 1d of the side surface portion 1c of the housing 1. Therefore, when the housing 1 is held by the one hand H such that one of the stable surfaces 1a and 1b is in contact with the palm Ha, the holding state of the housing 1 can be detected by the necessary minimum number (two) of a pair of holding detection sensors 2a and 2a′, and it is possible to reduce manufacturing costs and the current consumption.

In the embodiment described above, in a case where the holding detection sensors 2a and 2a′ detect approaching or movement of the human body within a given time, and thus the amount of change in the electrostatic capacity of the sensors 2a and 2a′ is equal to or greater than a threshold value, the control section 3 determines that the housing 1 is being held by the one hand H. Therefore, when the housing 1 is held to be gripped by the one hand H, even if the timings when the palm Ha and the fingers F2 to F5 of the one hand H approach or are in contact with the holding detection sensors 2a and 2a′ are the same or are different from each other within a given time, it is possible to reliably detect the holding state.

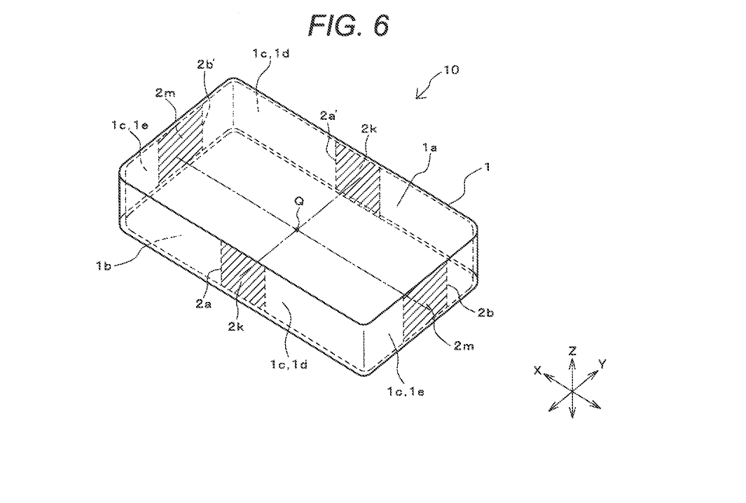

One or more embodiments of the invention can adopt various embodiments other than the above-described embodiment. For example, in the above-described embodiment, an example in which one input operation detection sensor 2b is disposed on the side surface portion 1c of the housing 1 is described, but one or more embodiments of the invention are not limited thereto. In addition to the example, a plurality of input operation detection sensors 2b and 2b′ may be disposed on the side surface portion 1c of the housing 1, as illustrated in FIG. 6.

In the example of FIG. 6, the pair of input operation detection sensors 2b and 2b′ as well as the pair of holding detection sensors 2a and 2a′ is symmetrically disposed on the side surface portion 1c of the housing 1. Specifically, the input operation detection sensors 2b and 2b′ are disposed in the vicinity of each side surface 1e of the side surface portion 1c so as to make a pair in a line-symmetric shape with respect to a straight line that passes through the center Q of the housing 1 and is parallel with the Y axis. The detection surfaces 2m of the input operation detection sensors 2b and 2b′ are parallel with the side surface 1e, and face a side opposite to the center Q of the housing 1. In this case, for example, if the input operation by the finger F1 and the like is detected by any of the input operation detection sensors 2b and 2b′ after the holding of the housing 1 by the one hand H is detected by the holding detection sensors 2a and 2a′, the control section 3 outputs a control signal to the communication section 4 so as to transmit a keyless entry signal to the vehicle-mounted control device 20 by using the communication section 4.

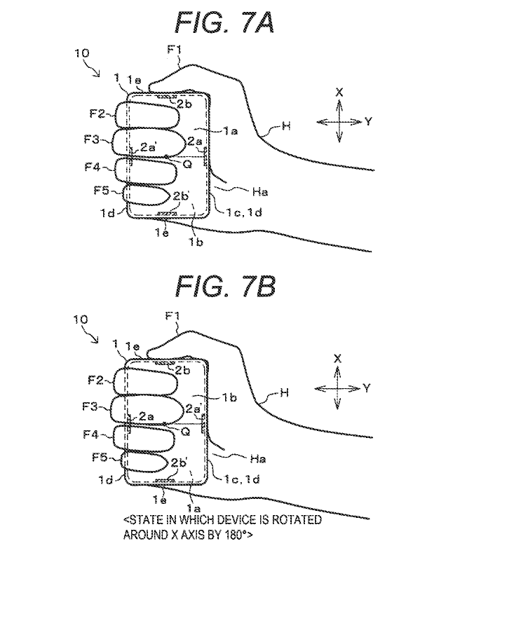

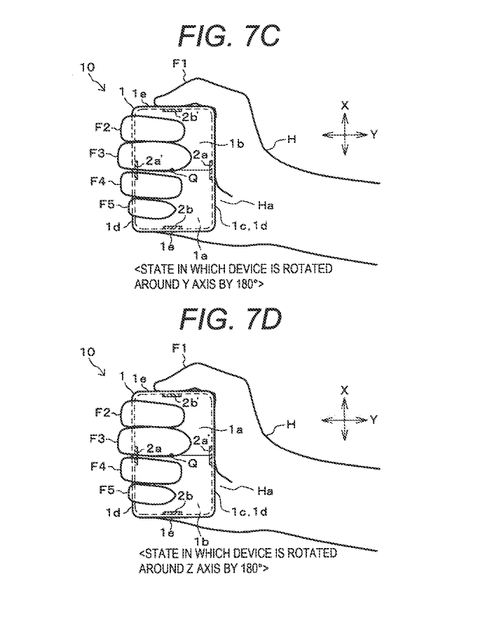

According to the portable electronic device 10 of FIG. 6, the housing 1 has a symmetric shape in the three axis directions X, Y, and Z which are orthogonal to each other, and the dimensions of the three axis directions X, Y, and Z are different from each other. Therefore, the user recognizes the three axis directions X, Y, and Z of the housing 1 by the tactile sense without visual observation, and thus, as illustrated in FIGS. 7A to 7D, it is possible to hold the housing 1 by the one hand H in a manner that any one of the stable surfaces 1a and 1b is in contact with the palm Ha and the long axis direction X of the housing 1 is parallel with the direction in which the fingers F2 to F5 are lined side by side. In this case, it is unnecessary to distinguish two opposite directions in the respective axial directions X, Y, and Z of the housing 1. Thus, as illustrated in FIGS. 7A to 7D, the degree of freedom of holding forms of the portable electronic device 10 is increased, and thereby the convenience and the operability can be further improved. In FIGS. 7A to 7D, FIG. 7B illustrates a state of the housing 1 being rotated around the X axis by 180° from the state of FIG. 7A, FIG. 7C illustrates a state of the housing 1 being rotated around the Y axis by 180° from the state of FIG. 7A, and FIG. 7D illustrates a state of the housing 1 being rotated around the Z axis by 180° from the state of FIG. 7A.

In a case where the housing 1 is held by the one hand H in any state of FIGS. 7A to 7D, since the palm Ha and the fingers F3 and F4 approach (or are in contact with) the holding detection sensors 2a and 2a′, it is possible to reliably detect the holding state of the housing 1 by the holding detection sensors 2a and 2a′. In addition, since any one of the input operation detection sensors 2b and 2b′ faces the thumb F1, the user can perform the input operation on any of the input operation detection sensors 2b and 2b′ by using the thumb F1 without visual observation, and thus it is possible to normally operate the portable electronic device 10 according to the input operation.

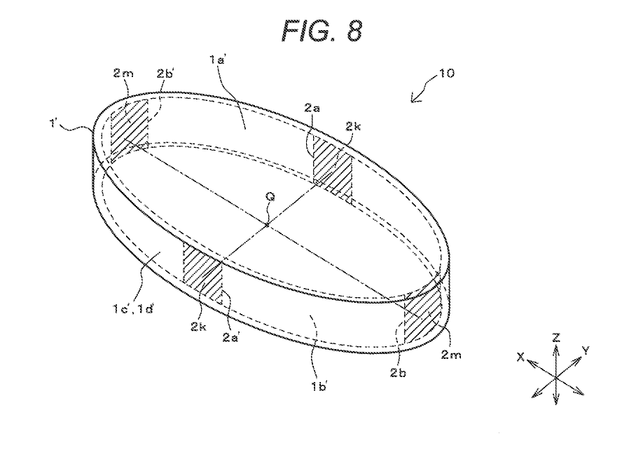

In addition, in the embodiments described above, an example in which the housing 1 formed in a thin rectangular parallelepiped shape is used is described, but one or more embodiments of the invention are not limited thereto. In addition to the example, a housing 1′ having an elliptical shape in a plan view and a rectangular shape in a side view, as illustrated in FIG. 8, may be used. In addition, a housing having any other shape may be used. Furthermore, the housing may not have a shape that is symmetric in all the three axis directions which are orthogonal to each other.

In the example of FIG. 8, the housing 1′ has a symmetric shape in the three axis directions X, Y, and Z which are orthogonal to each other, and the dimensions of the three axis directions X, Y, and Z are different from each other. The housing 1′ includes the stable surfaces 1a′ and 1b′ having the widest projected areas, and the side surface portion 1c′ that is present on the side of the stable surfaces 1a′ and 1b′. The pair of holding detection sensors 2a and 2a′ and the pair of input operation detection sensors 2b and 2b′ are symmetrically disposed on the side surface portion 1c′, respectively. The side surface portion 1c′ is an elliptical frame-shaped portion which is present on the side of the stable surfaces 1a′ and 1b′, and the side surface 1d′ (surface parallel with the Z axis in FIG. 8) that continues to the stable surfaces 1a′ and 1b′, and a region inside the side surface 1d′ and close to the side surface 1d′.

In addition, in the embodiments described above, the sensors 2a, 2a′, 2b, and 2b′ are disposed on the side surface portions 1c and 1c′ of the housings 1 and 1′ such that the detection surfaces 2k of the holding detection sensors 2a and 2a′ and the detection surfaces 2m of the input operation detection sensors 2b and 2b′ are orthogonal to each other. However, one or more embodiments of the invention are not limited thereto, and in addition to the example, the sensors may be disposed on the side surface portion of the housing such that the detection surface of the holding detection sensor and the detection surface of the input operation detection sensor are parallel with each other, or intersect with each other at an angle other than 90° C.

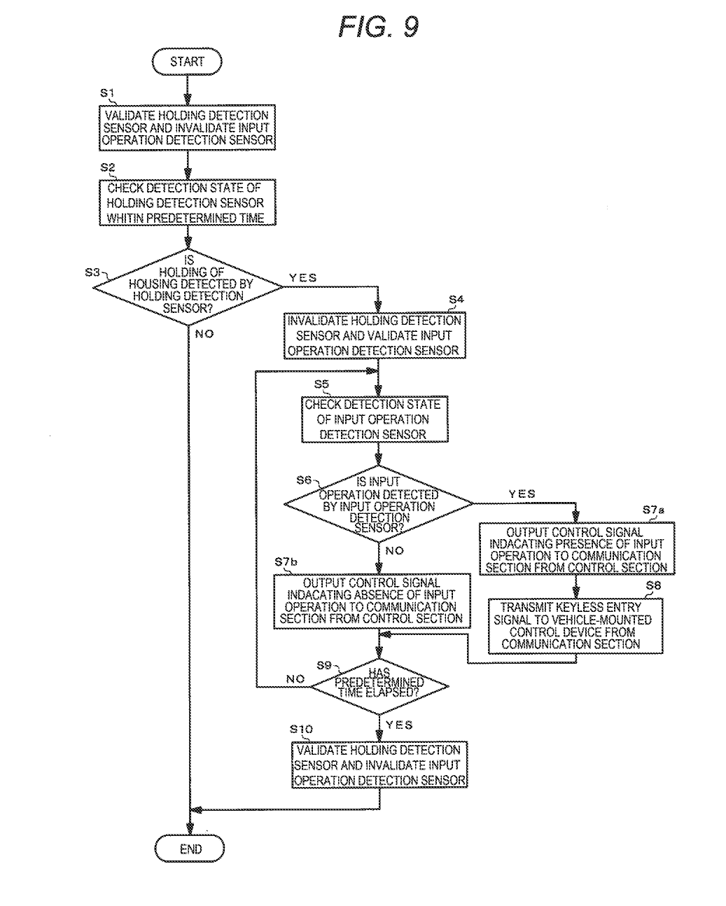

In addition, in the embodiment of FIG. 5, an example in which the control section 3 outputs a control signal to the communication section 4 only in a case where the input operation is detected within a predetermined time after the holding of the housing 1 is detected, is described, but one or more embodiments of the invention are not limited thereto. In addition to the example, as illustrated in FIG. 9, the control section 3 may output, to the communication section 4, a control signal based on the presence or absence of the detection of the input operation within a predetermined time after the holding of the housing 1 is detected (steps S7a and S7b).

Specifically, in FIG. 9, in a case where the input operation is detected by the input operation detection sensor 2b (step S6: YES) within a predetermined time after the holding of the housing 1 is detected by the holding detection sensors 2a and 2a′ (step S3: YES), the control section 3 outputs a control signal indicating the presence of the input operation to the communication section 4 (step S7a). Meanwhile, in a case where the input operation is not detected by the input operation detection sensor 2b (step S6: NO), the control section 3 outputs a control signal indicating the absence of the input operation to the communication section 4 (step S7b).

In addition, in the embodiment described above, an example in which the input operation detection sensors 2b and 2b′ are validated and the holding detection sensors 2a and 2a′ are invalidated within a predetermined time after the holding of the housing 1 is detected by the holding detection sensors 2a and 2a′ is described, but one or more embodiments of the invention are not limited thereto. In addition to the example, the input operation detection sensors 2b and 2b′ may be validated and the holding detection sensors 2a and 2a′ may be maintained to be in a valid state within a predetermined time after the holding of the housing 1 is detected by the holding detection sensors 2a and 2a′. In this case, within the predetermined time, the control section 3 may output a control signal to the communication section 4 on the basis of the detection results of the input operation detection sensors 2b and 2b′, regardless of the detection result of the holding detection sensors 2a and 2a′, and may transmit a radio signal to the vehicle-mounted control device 20 by using the communication section 4. In addition, the detection results of the holding detection sensors 2a and 2a′ may be displayed on a display section (not illustrated) such as an LED provided to the portable electronic device 10.

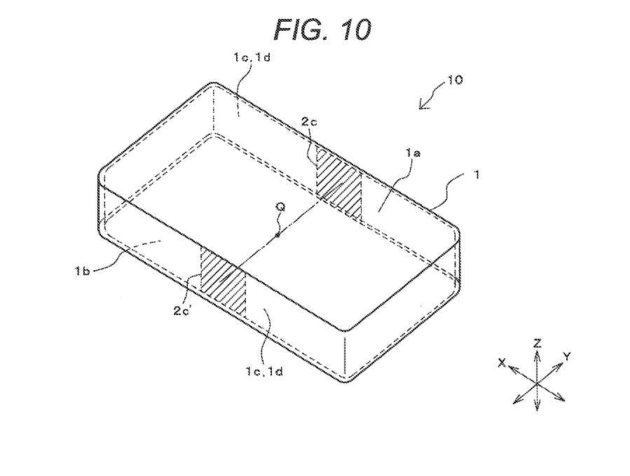

In addition, in the embodiment described above, an example in which a plurality of sensors provided to the housing include exclusive sensors 2a and 2a′ to holding detection (the holding detection units) and exclusive sensors 2b and 2b′ to the input operation detection (the input operation detection units) is described, but the holding detection unit may serve as the input operation detection unit. For example, as illustrated in FIG. 10, a plurality of holding and input operation detection sensors 2c and 2c′ which detect both the holding of the housing and the input operation may be disposed on the side surface portion 1c of the housing 1.

In the example of FIG. 10, the holding and input operation detection sensors 2c and 2c′ include proximity sensors, and are disposed, one by one, in the vicinity of the respective side surfaces 1d of the side surface portion 1c of the housing 1. In addition, the holding and input operation detection sensors 2c and 2c′ are symmetrically disposed with respect to the center Q of the housing 1. Then, if approaching (or contact) of a human body is detected by both the holding and input operation detection sensors 2c and 2c′, the control section determines that the housing 1 is being held. Thereafter, if a predetermined operation (knocking operation or the like) of the human body is detected by at least one of the holding and input operation detection sensors 2c and 2c′, the control section determines that the input operation is performed.

In doing so, it is possible to hold the housing 1 by the one hand H in a manner that any one of the stable surfaces 1a and 1b is in contact with the palm Ha of the one hand H, and the long axis direction X of the housing 1 is parallel with the direction in which the fingers F2 to F5 are lined side by side, and thereby it is possible to detect the holding and the input operation by the holding and input operation detection sensors 2c and 2c′. In addition, the number of installed proximity sensors, which configure the holding and input operation detection sensors 2c and 2c′, is reduced, and thus it is possible to reduce the manufacturing costs and the power consumption. However, the number of installed holding and input operation detection sensors is not limited to two, and the installation position is not limited to the example of FIG. 10. The number of installed holding and input operation detection sensors may be set to an arbitrary number, and the installation position may be set to an arbitrary position of the housing.

In addition, in the embodiment described above, an example in which the capacitance type proximity sensors 2a, 2a′, 2b, 2b′, and 2c are used as the holding detection unit and the input operation detection unit is described, but one or more embodiments of the invention are not limited thereto. In addition to the example, an electrical sensor such as an electric field sensor or a switch or a button including a mechanical component may be used as the holding detection unit and the input operation detection unit. In addition, the holding detection unit and the input operation detection unit may be disposed in the vicinity of the stable surface such as an upper surface and a lower surface in addition to the side surface portion of the housing. Further, the number of installed holding detection units and installed input operation detection units is not limited to the number of the installed holding detection units and the installed input operation detection units of the embodiment describe above, and, may be set according to the size of the housing.

Furthermore, in the embodiment described above, an example in which one or more embodiments of the invention are applied to the portable electronic device 10 including a keyless remote controller for a vehicle is described. However, one or more embodiments of the invention can be applied to other portable electronic devices such as other keyless remote controllers for a vehicle, such as a keyless remote controller for a motorcycle or a keyless remote controller for a large-sized motor vehicle, or remote controllers of a car navigation or audio equipment.

While the invention has been described with respect to a limited number of embodiments, those skilled in the art, having benefit of this disclosure, will appreciate that other embodiments can be devised which do not depart from the scope of the invention as disclosed herein. According, the scope of the invention should be limited only by the attached claims.

1. A portable electronic device comprising:
a housing that is configured to be held by one hand of a human being;
a holding detection unit that detects holding of the housing by the one hand;
an input operation detection unit that detects an input operation; and
a control section that outputs a control signal based on detection results of the holding detection unit and the input operation detection unit,
wherein the control section validates the input operation detection unit if the holding of the housing is detected by the holding detection unit, and after the validation, outputs a control signal based on a detection result of the input operation detection unit regardless of the detection result of the holding detection unit.

2. The portable electronic device according to claim 1,
wherein the control section invalidates the holding detection unit and validates the input operation detection unit within a predetermined time after the holding of the housing is detected by the holding detection unit, and outputs a control signal based on the detection result of the input operation detection unit, and
wherein the control section validates the holding detection unit and invalidates the input operation detection unit before the holding detection unit detects the holding of the housing or after the predetermined time elapses after the holding of the housing is detected.

3. The portable electronic device according to claim 1,
wherein the housing comprises a stable surface that is a surface having a widest projected area, and a side surface portion that is present on a side of the stable surface, and
wherein the holding detection unit and the input operation detection unit are disposed on the side surface portion.

4. The portable electronic device according to claim 3,
wherein a plurality of the holding detection units are symmetrically disposed on the side surface portion of the housing.

5. The portable electronic device according to claim 1,
wherein the holding detection unit comprises a plurality of sensors that detect approaching or movement of a human body, and
wherein when the plurality of sensors detect the approaching or the movement of the human body within a predetermined time, the control section determines that the housing is being held.

6. The portable electronic device according to claim 1,
wherein the portable electronic device comprises a keyless remote controller for a vehicle, and
wherein the portable electronic device further comprises:
a communication section that transmits a radio signal to a vehicle-mounted control device that is mounted in a vehicle, based on the control signal output from the control section.

7. The portable electronic device according to claim 1,
wherein the holding detection unit also serves as the input operation detection unit.
